(19) United States
(12) Patent Application Publication
(10) Pub. No.: US 2023/0028542 A1
(43) Pub. Date: Jan. 26, 2023

(54) ENERGIZATION CONTROLLER

(71) Applicant: Yazaki Corporation, Tokyo (JP)

(72) Inventors: Teppei DOI, Shizuoka (JP); Joh FUJIMOTO, Shizuoka (JP); Kazuhiro YAMAMOTO, Shizuoka (JP)

(73) Assignee: Yazaki Corporation, Tokyo (JP)

(21) Appl. No.: 17/858,648

(22) Filed: Jul. 6, 2022

(30) Foreign Application Priority Data
Jul. 14, 2021 (JP) 2021-116571

(51) Int. Cl. H05K 1/11; H05K 1/14; H02G 3/16; H01H 45/04

(52) U.S. Cl. CPC H05K 1/11; H05K 1/14; H02G 3/16; H01H 45/04

(57) ABSTRACT

An energization controller that is easily and inexpensively adaptable to diversified configurations of a load is provided. The energization controller includes a parent board mounted with a mechanical relay that allows or interrupts flow of a current between a power source and a load, a child board mounted with a load control component that drives the load or transmits a signal to the load, and a connecting part that connects the parent board and the child board to each other.

### TECHNICAL FIELD

The present invention relates to an energization controller.

### BACKGROUND

Conventionally, a vehicle is mounted with a power source and various electronic devices (loads) that receive power from the power source. An energization controller (so-called electrical connection box) constituted of an aggregation of electrical components such as relays is installed between the power source and the electronic devices (e.g., see Patent Document 1). The electronic component module (i.e., the energization controller) described in Patent Document 1 includes a first circuit board to which a wire harness and a fuse are connected, and a second circuit board that includes a plurality of relays and that is connected to the first circuit board.

### RELATED ART DOCUMENT

Patent Document 1: JP 2019-145681 A

### SUMMARY OF THE INVENTION

### Problem to be Solved by the Invention

In recent years, variation in type and number of electronic devices to be mounted on the vehicle, i.e., configuration of the load, has been diversified. The diversified configurations of the load result in the need for a change in the way of energization (i.e., allowing and interrupting flow of a current) between the power source and the loads, causing the need to replace a board that constitutes the energization controller. However, in the electronic component module described in Patent Document 1, the first circuit board and the second circuit board together constitute a single board having a function of relaying the electric power. Thus, when the configuration of the load is diversified, it is difficult to avoid significant changes in the entire configuration of the board because it is not possible to replace only one of the first circuit board and the second circuit board. This causes an increase in man-hours required for making changes in the board associated with the diversified configurations of the load, leading to an increase in the product cost of the energization controller.

In view of the above problem, an object of the present invention is to provide an energization controller that is easily and inexpensively adaptable to the diversified configurations of the load.

### Solution to Problem

To solve the above problem and achieve the object described above, the present invention provides, in a first aspect, an energization controller configured to control flow of a current between a power source and a load, including a first board mounted with a relay that allows or interrupts flow of a current between the power source and the load, a second board mounted with a load control component that drives the load or transmits a signal to the load, and a connecting part that connects the first board and the second board to each other.

### Advantageous Effect of the Invention

According to the present invention, it is possible to provide an energization controller that is easily and inexpensively adaptable to the diversified configurations of the load.

### BRIEF DESCRIPTION OF THE DRAWINGS

FIG. 1 is a perspective view of an energization controller according to one embodiment of the present invention, in which a housing thereof is removed;

FIG. 2 is a perspective view of a parent board of the energization controller;

FIG. 3 is a perspective view of a child board of the energization controller; and

FIG. 4 is an overall perspective view of the energization controller.

### DETAILED DESCRIPTION OF THE EXEMPLARY EMBODIMENT

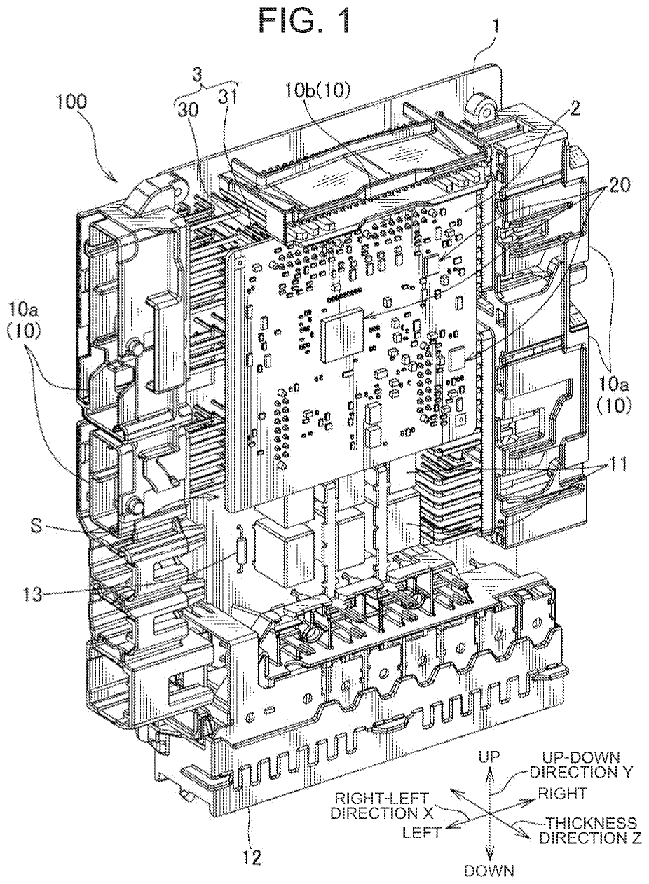

In the following, one embodiment of the present invention is described with reference to FIG. 1 to FIG. 4. An energization controller 100 is a device configured to control energization (i.e., control flow of a current) between a power source (not shown) and a load (not shown) that receives electric power from the power source. The energization controller 100 includes a parent board 1 (first board) a main function of which is to relay electric power between the power source and the load, a child board 2 (second board) a main function of which is to control the load, a connecting part 3 that connects the parent board 1 and the child board 2 to each other, and a housing 4 that accommodates the parent board 1 and the child board 2 with the parent and child boards connected to each other by the connecting part 3. In the drawings, an arrow X, an arrow Y and an arrow Z are directions perpendicular to one another. A short-side direction of the parent board 1 and of the child board 2 is indicated by the arrow X and is referred to as “right-left direction X”. A long-side direction of the parent board 1 and of the child board 2 is indicated by the arrow Y and is referred to as “up-down direction Y”. A thickness direction of the parent board 1 and of the child board 2 is indicated by the arrow Z and is referred to as “thickness direction Z”. In each drawing, the left side of the drawing corresponds to the left side in the right-left direction X, and the right side in the drawing corresponds to the right side in the right-left direction X.

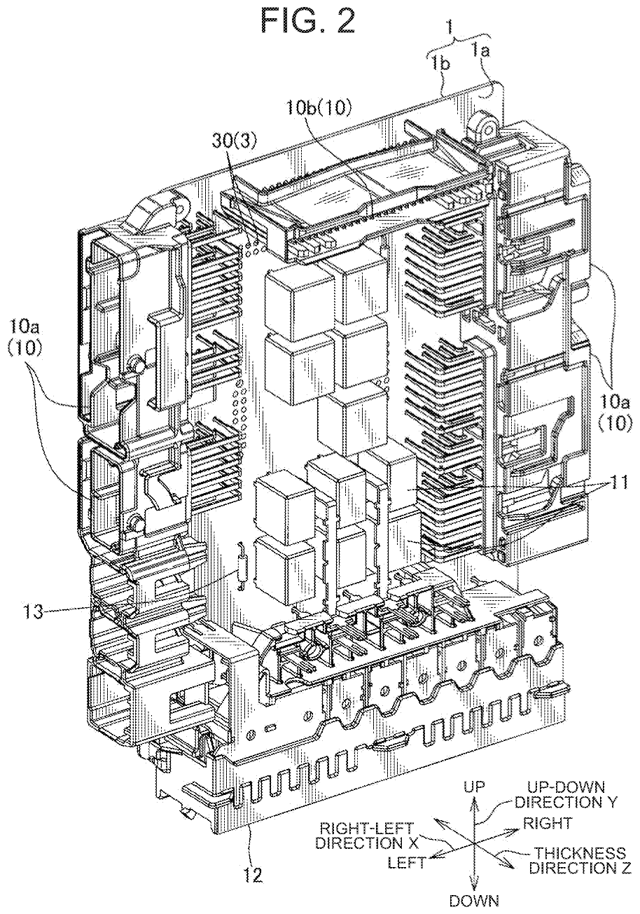

The parent board 1 is a board mounted with an electric circuit for transmitting electric power inputted from the power source to the energization controller 100 to the load, and the parent board 1 is formed in a substantially rectangular shape that is long in the up-down direction Y. As shown in FIG. 2, the parent board 1 includes a connector block 10, a plurality of mechanical relays 11 (relay), a fuse block 12 and a resistor 13. The connector block 10, the mechanical relays 11, the fuse block 12 and the resistor 13 are connected to one another by a printed wiring (not shown). The connector block 10 is a component that connects the energization controller 100 and an external device, and the connector block 10 includes a printed circuit board terminal 10a configured to be connected to the power source or the load, and an external signal terminal 10b configured to be connected to a control component such as an ECU that controls the mechanical relays 11.

The printed circuit board terminal 10a is formed in a substantially cubic box shape. The plurality of printed circuit board terminals 10a is disposed on a left end portion and a right end portion of the parent board 1 and is aligned in the up-down direction Y. Each printed circuit board terminal 10a includes an opening that opens toward the outside of the parent board 1, such that a connector of an electric wire connected to the power source or the load can be inserted into the printed circuit board terminal 10a through the opening. The external signal terminal 10b is formed in a substantially rectangular parallelepiped box shape that is elongated in the right-left direction X. The external signal terminal 10b is disposed on a mount face 1a of the parent board 1 on which the printed wiring is provided, and is disposed on a central upper portion in the up-down direction Y of the mount face 1a so as to extend in the right-left direction X along an upper end portion of the parent board 1. The external signal terminal 10b stands from the mount face 1a in the thickness direction Z and includes an opening that opens in the same direction. A connector of an electric wire connected to the control component as described above can be inserted into the external signal terminal 10b through this opening.

The mechanical relay 11 is a so-called switch that transmits a current that has inputted from the power source to the energization controller 100 to the load, and the plurality of mechanical relays 11 is provided at the parent board 1. Each mechanical relay 11 is disposed at a substantially central portion of the mount face 1a, and is surrounded by the connector block 10 and the fuse block 12 in the right-left direction X and the up-down direction Y. The fuse block 12 is a component that accommodates a fuse (not shown) and is formed in a substantially rectangular parallelepiped box shape that is elongated in the right-left direction X. The fuse block 12 is disposed on a lower end portion of the parent board 1 along the right-left direction X. The resistor 13 is a member that adjusts an amount of electricity flowing through the energization controller 100, and is disposed at a predetermined position on the mount face 1a. In this embodiment, the resistor 13 is disposed in the vicinity of the mechanical relay 11.

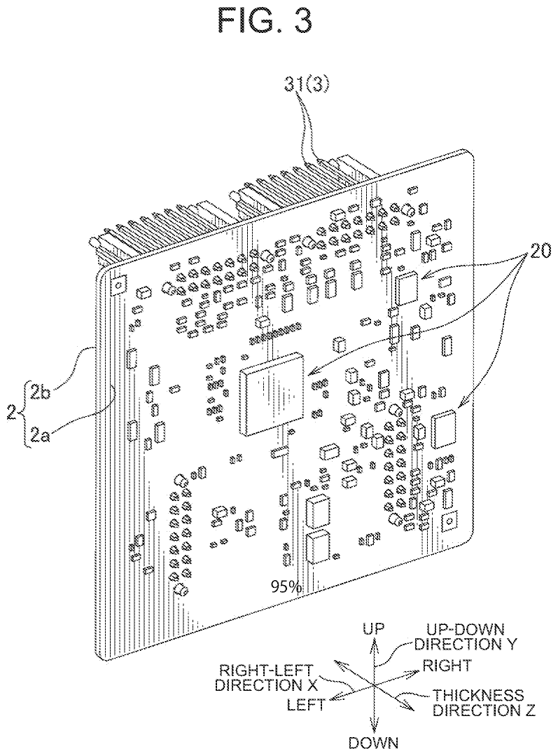

The child board 2 is a board mounted with an electric circuit for driving the load or transmitting a signal to the load, and is formed in a substantially rectangular plate shape one side of which has a dimension smaller than a dimension of the parent board 1 in the right-left direction X. As shown in FIG. 3, the child board 2 includes a load control component 20. The load control component 20 includes, for example, a semiconductor relay that allows or interrupts the flow of a current on the child board 2 such as a chip capacitor or an aluminum electrolytic capacitor. The load control component 20 further includes a control component such as a microcontroller that controls the semiconductor relay, and a fuse and a chip resistor. The respective load control components 20 are disposed on a mount face 2a of the child board 2 on which a printed wiring (not shown) is provided, and are connected to one another by the printed wiring. The child board 2 is arranged to be spaced apart from the mount face 1a of the parent board 1 in the thickness direction Z, such that a back face 2b of the child board 2 which is a face opposite to the mount face 2a faces the parent board 1. With this arrangement, the parent board 1 and the child board 2 face each other in the thickness direction Z with the space between each other. Further, a gap S is created between the parent board 1 and the child board 2, as shown in FIG. 1, and various electronic components may be placed within this gap S. For example, in this embodiment, one or some of the plurality of mechanical relays 11 may be placed in the gap S.

The connecting part 3 is a component that connects the parent board 1 and the child board 2 to each other. The connecting part 3 includes a through-hole 30 formed on the parent board 1 and a pin header 31 mounted on the child board 2. The through-hole 30 is a hole that penetrates through the parent board 1 in the thickness direction Z. The plurality of through-holes 30 is formed along the right-left direction X at an upper end portion of the parent board 1 below the external signal terminal 10b in the up-down direction Y. Each through-hole 30 is configured such that a protruding end of the pin header 31 can be inserted and fixed therein. Thus, a dimension of an inner diameter of each through-hole 30 is set to be substantially the same as a dimension of an outer diameter of the pin header 31, or slightly larger than the dimension of the outer diameter of the pin header 31. The pin header 31 is a component to be inserted into the through-hole 30, and the plurality of pin headers 31 is arranged along the right-left direction X on an upper end portion of the child board 2. The pin header 31 is formed so as to protrude in the thickness direction Z from the back face 2b of the child board 2 toward the mount face la of the parent board 1. With this configuration, when the pin headers 31 are inserted into the through-holes 30, the parent board 1 and the child board 2 are electrically connected to each other and the child board 2 is mechanically fixed with respect to the parent board 1. Further, the dimension of the above-described gap S in the thickness direction Z is substantially the same as a length obtained by subtracting, from the dimension in the protruding direction of the entire pin header 31, the dimension in the protruding direction of the protruding end of the pin header 31 that is inserted into the through-hole 30.

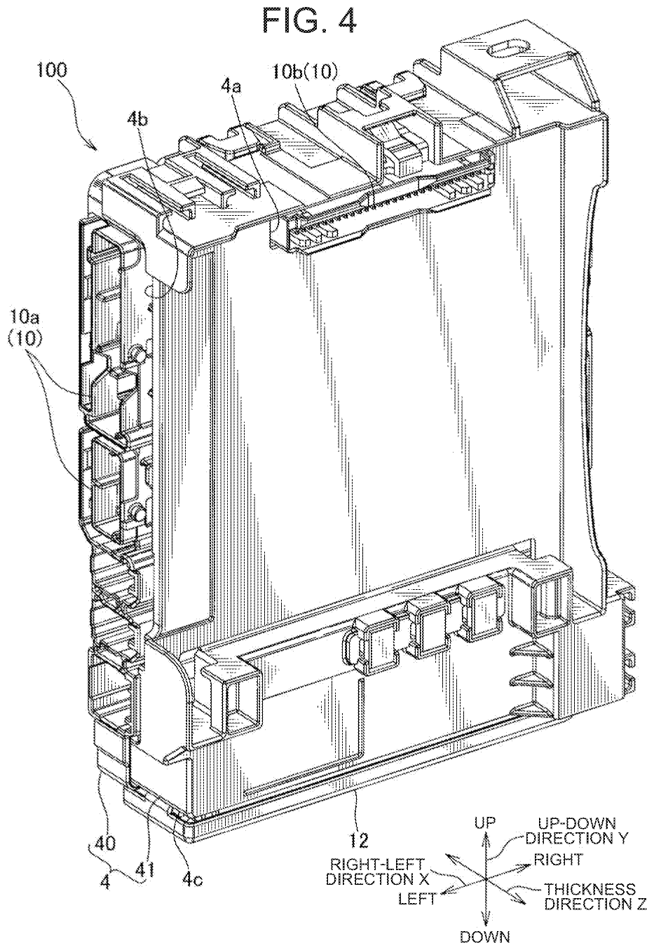

As shown in FIG. 4, the housing 4 is a component that accommodates the parent board 1 and the child board 2 that are connected to each other by the connecting part 3, and is formed in a substantially rectangular parallelepiped box shape which is long in the up-down direction Y. This housing 4 includes a back cover 40 and a front cover 41 that face each other in the thickness direction Z. The back cover 40 is a substantially rectangular frame member that is long in the up-down direction Y, and an outer peripheral edge portion of the back cover 40 is standing in the thickness direction Z toward the front cover 41 side. The front cover 41 is a substantially rectangular frame member that is long in the up-down direction Y, and an outer peripheral edge portion of the front cover 41 is standing in the thickness direction Z toward the back cover 40 side. An external signal opening 4a is formed on a part of the front cover 41 corresponding to the external signal terminal 10b so as to penetrate the front cover 41 in the thickness direction Z. The external signal opening 4a is an opening for passing therethrough the external signal terminal 10b. When the parent board 1 is accommodated in the housing 4, the standing tip of the external signal terminal 10b protrudes outward through the external signal opening 4a. This facilitates the insertion of the connector of the electric wire connected to the control component such as an ECU into the external signal terminal 10b.

The back cover 40 and the front cover 41 can be fitted to each other via their peripheral edge portions. Notches extending in the up-down direction Y are formed on the left-side part and the right-side part of the peripheral edge portions of the back cover 40 and the front cover 41, respectively. Notches extending in the right-left direction X are formed on the lower-side part of the peripheral edge portions of the back cover 40 and the front cover 41, respectively. Thus, in the state where the back cover 40 and the front cover 41 are fitted to each other, i.e., in the state where the housing 4 is formed, connector openings 4b which open in the in-out direction are formed on both right and left walls of the housing 4, and a fuse opening 4c which opens in the in-out direction is formed on a lower wall of the housing 4. The connector opening 4b is an opening for placing therein the printed circuit board terminal 10a. When the parent board 1 is accommodated in the housing 4, a left end of the printed circuit board terminal 10a protrudes outward from the left connector opening 4b, and a right end of the printed circuit board terminal 10a protrudes outward from the right connector opening 4b. This configuration facilitates the insertion of the connector of the electric wire connected to the power source or the load into the printed circuit board terminal 10a. The fuse opening 4c is an opening for placing therein the fuse block 12. When the parent board 1 is housed in the housing 4, a lower end of the fuse block 12 protrudes downward from the fuse opening 4c.

The energization controller 100 is assembled in accordance with the following procedure. First, as shown in FIG. 2, the connector block 10, the mechanical relays 11, the fuse block 12 and the resistor 13 are mounted on predetermined positions on the parent board 1. Further, as shown in FIG. 3, the load control components 20 (e.g., semiconductor relays, control components, fuses, chip resistors) and the pin headers 31 are mounted on the child board 2. Then, by inserting the pin headers 31 into the through-holes 30, the parent board 1 and the child board 2 are electrically connected to each other and mechanically fixed with respect to each other. Then, the back cover 40 of the housing 4 is placed on the back face 1b side of the parent board 1, and the front cover 41 of the housing 4 is placed on the mount face 2a side of the child board 2, and the back cover 40 and the front cover 41 are fitted to each other with the parent board 1 and the child board 2 sandwiched therebetween in the thickness direction Z. Then, the connectors of the electric wires connected to the power source, the load and the control component such as an ECU are inserted into the connector block 10 to form an electric path between the power source and the load.

In the energization controller 100 having such a configuration, a current or an electrical signal inputted from one connector block 10 passes through the printed wiring on the parent board 1 and transmitted to the fuse block 12, for example. Thereafter, it returns to the printed wiring on the parent board 1 and outputted from another connector block 10 to an external component. Also, a current or an electrical signal inputted from one connector block 10 passes through the printed wiring on the parent board 1 and transmitted from the through-hole 30 to the pin header 31. Thereafter, it is transmitted to the printed wiring on the child board 2, and passes the pin header 31 and the through-hole 30 again to return to the printed wiring on the parent board 1, and outputted from another connector block 10 to an external component. On the parent board 1, the mechanical relay 11 applied with control by the control component such as an ECU via the external signal terminal 10b allows and interrupts flow of a current on the electric path, and thereby relays the electric power between the power source and the load. On the child board 2, the semiconductor relay applied with control by the control component mounted on the child board 2 itself allows and interrupts flow of a current on the electric path, thereby driving the load or transmitting the signal to the load.

According to the embodiment described above, the energization controller 100 includes the parent board 1 mounted with the mechanical relays 11 that allow and interrupt flow of a current between the power source and the load, the child board 2 mounted with the load control components 20 that drive the load or transmit a signal to the load, and the connecting part 3 that connects the parent board 1 and the child board 2 to each other.

According to the present invention, the mechanical relays 11 that allow and interrupt flow of a current between the power source and the load and the load control components 20 that control the load are disposed on the separate boards. Thus, when the configuration of the load is diversified, that is, when the load itself is to be exchanged or a system having an extended function is to be added to the load, and thus when there is a need to make a change in or addition to the mechanical relays 11, it is possible to adapt to this diversified configuration of the load by simply changing the configuration of the parent board 1. Similarly, even when there is a need to make a change in or addition to the load control component 20 associated with the above-described diversified configuration of the load, the configuration of the child board 2 can be simply changed to adapt to the diversified configuration of the load. Furthermore, depending on the configuration of the load, the energization controller 100 may be required to have only a function to relay the power as in the conventional case. In this case, by simply removing the child board 2 from the parent board 1, it is possible to easily adapt to this case without making any changes in the parent board 1. Thus, as compared with the energization controller that requires a change in the configuration of the entire board associated with the diversified configurations of the load, man-hours required for changing the board can be reduced, and thus the product cost for the energization controller 100 can be reduced. Consequently, it is possible to provide the energization controller 100 which can easily and inexpensively adapt to the diversified configuration of the load.

Further, according to the embodiment described above, the parent board 1 and the child board 2 are arranged to face each other in the thickness direction Z with the gap between each other, and are electrically connected to each other and mechanically fixed to each other by the connecting part 3 including the through-holes 30 and the pin headers 31. Thus, it is possible to prevent an increase in the dimensions of the parent board 1 and the child board 2 of the energization controller 100 in the right-left direction X and the up-down direction Y. Consequently, the energization controller 100 can be downsized. Further, since the gap S is created between the parent board 1 and the child board 2, it is possible to place the component such as the mechanical relay 11 in the gap S. Consequently, as compared with the configuration without the gap S, the energization controller 100 can be downsized for the dimension of the mechanical relay 11 in the right-left direction X, the up-down direction Y, or the thickness direction Z.

Further, according to the embodiment described above, the connecting part 3 is provided at the end portions of the parent board 1 and the child board 2. Thus, as compared with the configuration in which the connecting part 3 is provided in the central portions of the parent board 1 and the child board 2, a mounting space for mounting the mechanical relays 11 and the load control components 20 is less likely to be separated by the connecting part 3. Consequently, it is possible to increase the degree of freedom in the arrangement of the mechanical relays 11 and the load control components 20.

Embodiments of the present invention have been described with reference to the drawings, but a specific configuration of the present invention is not limited to these embodiments, thus modifications made to the design without departing from the gist of the present invention are still within the present invention. For example, in this embodiment, the through-holes 30 constituting the connecting part 3 are formed on the parent board 1, and the pin headers 31 are mounted on the child board 2. However, the configuration of the connecting part 3 is not limited to this. That is, the pin headers 31 may be mounted on the parent board 1, and the through-holes 30 may be formed on the child board 2. Further, rather than constituting the connecting part 3 with the through-holes 30 and the pin headers 31, a dedicated connecting terminal may be provided to connect the parent board 1 and the child board 2 to each other. Moreover, the electrical connection and the mechanical fixation for the parent board 1 and the child board 2 may be provided using separate parts. For example, a dedicated connecting terminal may be used for the electrical connection between the parent board 1 and the child board 2, while one of the parent board 1 and the child board 2 may be supported by a dedicated base and mechanically fixed with respect to the other one of the parent board 1 and the child board 2. Further, in this embodiment, the connecting part 3 is provided on the end portions of the parent board 1 and the child board 2. However, the connecting part 3 may be provided on the central portions of the parent board 1 and the child board 2. In this case, the spaces at the end portions of the parent board 1 and the child board 2 can be utilized efficiently.

Further, in this embodiment, the dimensions of the child board 2 in the right-left direction X and the up-down direction Y are set smaller than the dimensions of the parent board 1 in the right-left direction X and the up-down direction Y, respectively. However, the dimensions of the child board 2 are not limited to these. The respective dimensions of the child board 2 in the right-left direction X and the up-down direction Y may be the same as those of the parent board 1, or may be larger than those of the parent board 1. Further, the parent board 1 and the child board 2 do not need to be arranged to face each other in the thickness direction Z with the gap between each other. For example, a mounting space for the child board 2 may be provided on the mount face la of the parent board 1, and the child board 2 may be mounted in this mounting space. This configuration can also provide the advantageous effect similar to the above-described embodiment, and moreover, it can reduce the dimension of the energization controller 100 in the thickness direction Z so the height of the energization controller 100 can be reduced.

The components such as the mechanical relays 11 to be mounted on the parent board 1 and the load control components 20 to be mounted on the child board 2 are shown in this embodiment for the illustration purpose only. These components to be mounted may be omitted, changed, or added appropriately depending on the configuration of the power source and load. For example, the parent board 1 may be mounted with a relay such as a semiconductor relay and a control component for controlling the relay in order to add to the parent board 1 a function for driving the load and a function for transmitting a signal to the load. Further, the child board 2 may be mounted with the mechanical relay 11 in order to add thereto a function to relay the electric power between the power source and the load.

### LIST OF REFERENCE SIGNS

100 energization controller
1 parent board (first board)
11 mechanical relay (relay)
2 child board (second board)
20 load control component
3 connecting part

What is claimed is:

1. An energization controller configured to control flow of a current between a power source and a load, comprising:
a first board mounted with a relay that allows or interrupts flow of a current between the power source and the load;
a second board mounted with a load control component that drives the load or transmits a signal to the load; and
a connecting part that connects the first board and the second board to each other.

2. The energization controller according to claim 1, wherein
the first board and the second board are arranged to face each other in a thickness direction with a gap between each other, and
the first board and the second board are electrically connected to each other and mechanically fixed to each other by the connecting part.

3. The energization controller according to claim 1, wherein the connecting part is provided at end portions of the first board and the second board.
